(19) United States
(12) Patent Application Publication
(10) Pub. No.: US 2017/0199511 A1
(43) Pub. Date: Jul. 13, 2017

(54) SIGNAL DETECTION METHOLODOGY FOR FABRICATION CONTROL

(71) Applicant: GLOBALFOUNDRIES Inc., Grand Cayman (KY)

(72) Inventors: Dongsuk PARK, Mechanicville, NY (US); Alok VAID, Ballston Lake, NY (US); Binod Kumar Gopalakrishn NAIR, Clifton Park, NY (US)

(21) Appl. No.: 14/993,320

(22) Filed: Jan. 12, 2016

(51) Int. Cl. G05B 19/4099

(52) U.S. Cl. CPC G05B 19/4099; G05B 2219/32019

(57) ABSTRACT

Methodologies and a device for simulating individual process steps and producing parameters representing each individual process signal profile are provided. Embodiments include collecting, by way of a programmed processor, wafer level data in the form of electrical signatures during processing steps in the production of a semiconductor device; converting the electrical signatures during each of the processing steps into signal matrix (MS) modeling parameters; comparing the MS modeling parameters to predefined MS modeling parameters; and adjusting at least one processing step based on a result of the comparing step for process control.

### TECHNICAL FIELD

The present disclosure relates to a method and device for utilizing signal detection technology for fabrication (FAB) control. In particular, the present disclosure relates to signal detection technology for semiconductor devices in the 32 nanometer (nm) technology node and beyond.

### BACKGROUND

Signal detection methodology has been used in overlay misalignment modeling for semiconductor devices and for lens aberration analysis. Full scale wafer measurement has been previously performed and the measurements have been converted to specific parameters and residuals. In other areas, measurement and simulation techniques are used for wafer stress modeling analysis in semiconductor devices.

With semiconductor yield control, every process of semiconductor manufacturing has its own electronic signature. These electronic signatures need to be maintained with sampled measurement, and most of the time the variation in one process can be compensated by other subsequent processes. However, the electronic signature can not be properly maintained with conventional methods.

A need therefore exists for methodology and an apparatus for quantifying and monitoring wafer profile signatures during each process of semiconductor manufacturing.

### SUMMARY

One aspect of the present disclosure is a method and apparatus for simulating individual process steps and producing parameters representing each individual process signal profile. Another aspect includes optimizing multiple processes within a wafer profile to obtain the optimum leakage and performance for a semiconductor device end product. Another aspect includes creating an electronic signature for each process step to generate a signal matrix (MS), or standard signature, which can serve as an early warning signal for FAB control.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: collecting, by way of a programmed processor, wafer level data in the form of electrical signatures during processing steps in the production of a semiconductor device; converting the electrical signatures during each of the processing steps into MS modeling parameters; comparing the MS modeling parameters to predefined MS modeling parameters; and adjusting at least one processing step based on a result of the comparing step for process control.

Aspects of the present disclosure include collecting the wafer level data during simulated processing steps in the production of the semiconductor device. Some aspects include the semiconductor device being represented with a simulated high density model. Other aspects include collecting critical dimension (CD), thickness, resistance (RS), overlay (OVL) and optical critical dimension (OCD) data with metrology systems. Certain aspects include collecting the wafer level data using 3^{rd} order modeling or higher. Further aspects include adjusting settings of processing equipment used in the actual production of the semiconductor device. Yet further aspects include collecting wafer level data across the wafer during the processing steps. Other aspects include optimizing the wafer level data to improve leakage of a semiconductor device end product. Additional aspects include optimizing the wafer level data to improve performance of a semiconductor device end product. Further aspects include generating an early warning signal prior to the adjusting step. Still further aspects include maintaining the electrical signatures for compensation purposes. Aspects additionally include controlling shape of distribution of MS modeling parameters.

Another aspect of the present disclosure is a device a simulator for generating a high density model of a semiconductor device during its processing; and a processor configured to: collect wafer level data in the form of electrical signatures during processing steps in the production of the semiconductor device; convert the electrical signatures during each of the processing steps into MS modeling parameters; compare the MS modeling parameters to predefined MS modeling parameters; and adjust at least one processing step based on a result of the comparing step for process control.

Aspects of the present disclosure include the processor being configured to collect CD, thickness, RS, OVL and OCD data with metrology systems. Other aspects include the processor being configured to collect the wafer level data with 3^{rd} order modeling or higher. Yet further aspects include the processor being configured to adjust one or more settings of processing equipment used in the actual production of the semiconductor device. Additional aspects include the processor being configured to generate an early warning signal prior to adjusting the one or more settings of processing equipment. Some aspects include the processor being configured to collect wafer level data across the wafer during the processing steps. Other aspects include the processor the processor being configured to optimize the wafer level data to improve leakage and performance of a semiconductor device end product.

Yet another aspect of the present disclosure is a method including collecting, by way of a programmed processor, wafer level data in the form of electrical signatures during simulated processing steps in the production of a semiconductor device; converting the electrical signatures during each of the processing steps into MS modeling parameters; comparing the MS modeling parameters to predefined MS modeling parameters; generating an early warning signal when a defective MS modeling parameter is detected; and adjusting at least one processing step based on a result of the comparing step for process control.

Aspects of the present disclosure include optimizing the wafer level data to improve leakage and performance of the semiconductor device end product.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 illustrates a radial pattern graph, according to an exemplary embodiment;

FIG. 2 illustrates a signal detection process flow chart, according to an exemplary embodiment;

FIG. 3 schematically illustrates a computer system for performing signal detection methodology, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

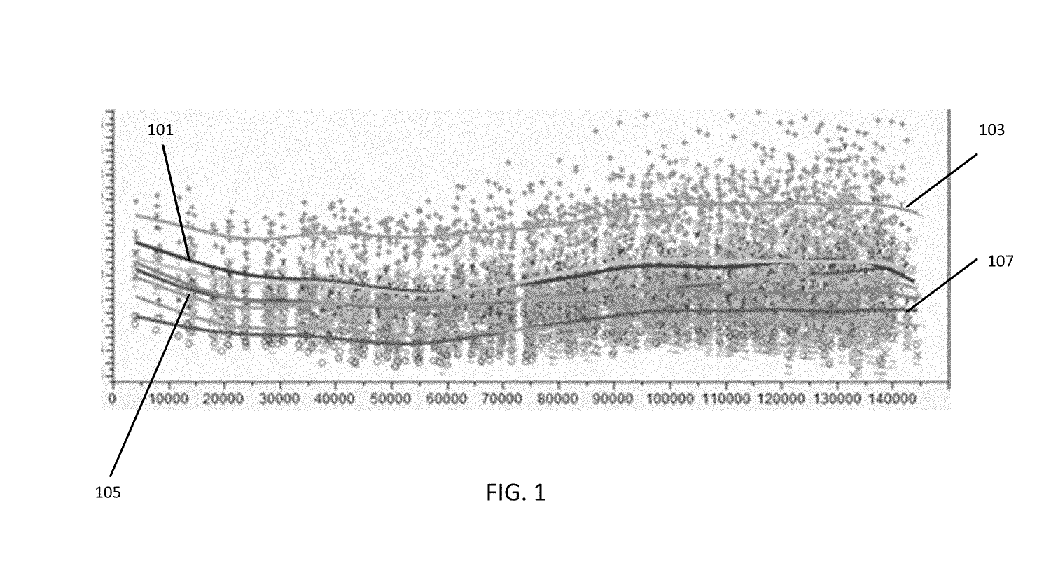

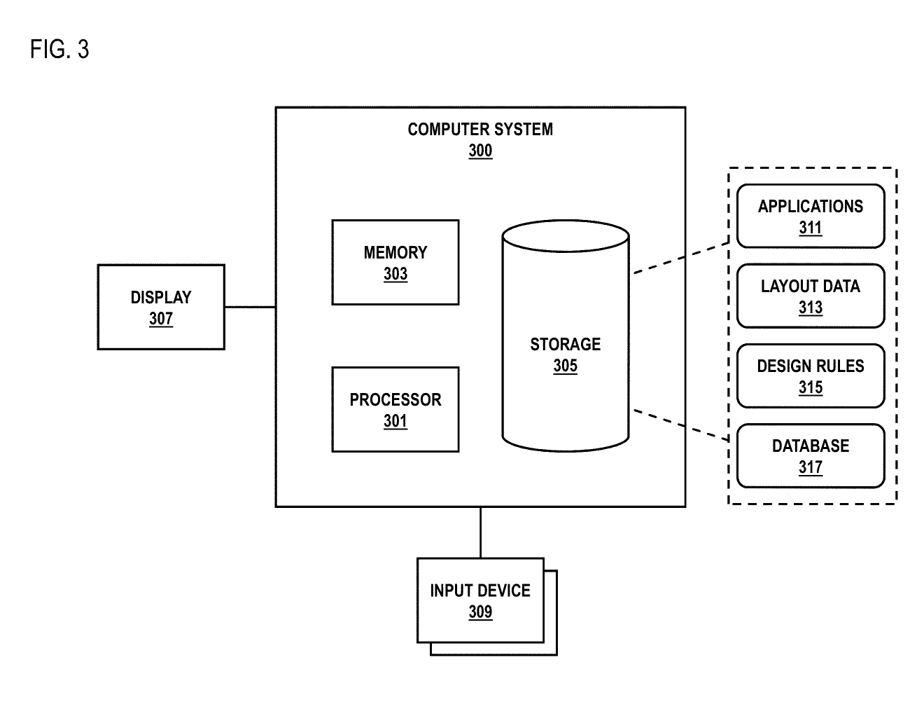

FIG. 1 illustrates a graph representing an example of a radial pattern of several processes, each process having its own electronic signature. The x-axis of the graph in FIG. 1 is a radius of an inspecting wafer, and the y-axis is any given measurement of a concerned process, including thickness or overlay vector or depth represented in measurement units such as Angstroms (Å), nm, micrometers (μm), etc. Wafer level data points are collected during each process and compiled for a radial signature build up. A shift in a radial pattern will cause more damage to the end product than a slight shift in the mean. In the graph of FIG. 1, each of the horizontal lines 101, 103, 105, and 107 represents a separate process having its own electronic signature. Lines 101, 103, 105, and 107 and their corresponding wafer level data points would be represented in different colors on a display device associated with a processor. The hardware for calculating and graphically displaying a radial graph is explained below with reference to FIG. 3.

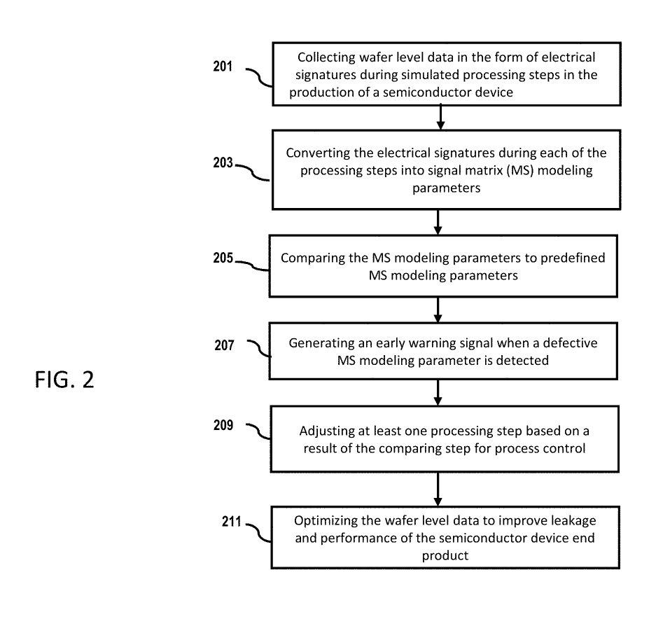

FIG. 2 illustrates a process flow in accordance with an exemplary embodiment. In Step 201, wafer level data is collected in the form of electrical signatures during simulated processing steps in the production of a semiconductor device. The semiconductor device is represented with a simulated high density mode. The collecting of wafer level data across the entre wafer surface includes collecting critical dimension (CD), thickness, resistance (RS), overlay (OVL) and optical critical dimension (OCD) data with metrology systems. In certain examples, hundreds and thousands of measurements can be collected by way of metrology equipment to provide a dense measurement. It is an objective to monitor and collect this data during each process of semiconductor manufacturing. The final electrical properties of the end product can be evaluated since the electrical properties have a certain electronic signature that can be compared to predetermined signatures.

The wafer level data is collected and used with 3^{rd} order modeling or higher. In certain embodiments, by using 3^{rd} order model of a Zernike polynomial, the amount of signature can be monitored in detail. Moreover, with 3^{rd} order modeling (or higher), residuals can be calculated using the following equation:

Σₛᵢₜₑ₀^{all site}Fx−each number=residual

The residual and shape parameters can be used as control signals.

In Step 203, the electrical signatures from Step 201 are converted during each of the processing steps into signal matrix (MS) modeling parameters. The signal must be maintained in order to be compensated. In Step 205, hardware, such as a programmed processor, compares the MS modeling parameters to predefined inline MS modeling parameters. It is an objective to control the shape of distribution of the MS modeling parameters. In accordance with exemplary embodiments, an early warning signal can be generated when a defective MS modeling parameter is detected (Step 207). This early warning signal can improve process control by providing sufficient warning in order for the processor or technician to make the necessary adjustments to semiconductor manufacturing equipment. In Step 209, at least one processing step can be adjusted based on a result of the comparing step to improve process control. As a result of this adjustment, the wafer level data is optimized to improve leakage and performance of the semiconductor device end product (Step 211).

The processes described herein may be implemented via software, hardware, firmware, or a combination thereof. Exemplary hardware (e.g., computing hardware) is schematically illustrated in FIG. 3. As shown, computer system 300 includes at least one processor 301, at least one memory 303, and at least one storage 305. The memory 303 may, for instance, include dynamic storage, static storage, or a combination thereof. Computer system 300 may be coupled to display 307 and one or more input devices 309, such as a keyboard and a pointing device. Display 307 may be utilized to provide one or more GUI interfaces. The computer system 300 is equipped with a graphics card. Input devices 309 may be utilized by users of computer system 300 to interact with, for instance, the GUI interfaces. Storage 305 may store applications 311, layout data (or information) 313, mask design rules 315, and at least one mask pattern database (or repository) 317. Applications 311 may include instructions (or computer program code) that when executed by processor 301 cause computer system 300 to perform one or more processes, such as one or more of the processes described herein. In exemplary embodiments, applications 311 may include one or more signature detection tools and modeling tools.

It is noted that, in various aspects, some or all of the techniques described herein are performed by computer system 300 in response to processor 301 executing one or more sequences of one or more processor instructions contained in memory 303. Such instructions, also called computer instructions, software and program code, may be read into memory 303 from another computer-readable medium such as a storage device or a network link. Execution of the sequences of instructions contained in memory 303 causes processor 301 to perform one or more of the method steps described herein. In alternative embodiments, hardware, such as application-specific integrated circuits (ASICs), may be used in place of or in combination with modeling software to implement the invention. Thus, embodiments of the invention are not limited to any specific combination of hardware and software, unless otherwise explicitly stated herein.

The embodiments of the present disclosure can achieve several technical effects including the ability to provide a clear shape of process signature tracking by using several parameters and residuals. The present disclosure enjoys industrial applicability in any of various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices, particularly for 32 nm technology nodes and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
collecting, by way of a programmed processor, wafer level data in the form of electrical signatures during processing steps in the production of a semiconductor device;
converting the electrical signatures during each of the processing steps into signal matrix (MS) modeling parameters;
comparing the MS modeling parameters to predefined MS modeling parameters; and
adjusting at least one processing step based on a result of the comparing step for process control.

2. The method according to claim 1, comprising:
collecting the wafer level data during simulated processing steps in the production of the semiconductor device.

3. The method according to claim 1, wherein the semiconductor device is represented with a simulated high density model.

3. The method according to claim 2, wherein collecting wafer level data comprises:
collecting critical dimension (CD), thickness, resistance (RS), overlay (OVL) and optical critical dimension (OCD) data with metrology systems.

4. The method according to claim 2, comprising:
collecting the wafer level data using 3^{rd} order modeling or higher.

5. The method according to claim 1, wherein adjusting at least one processing step comprises:
adjusting settings of processing equipment used in the actual production of the semiconductor device.

6. The method according to claim 1, comprising:
collecting wafer level data across the wafer during the processing steps.

7. The method of claim 2, further comprising:
optimizing the wafer level data to improve leakage of a semiconductor device end product.

8. The method according to claim 7, further comprising:
optimizing the wafer level data to improve performance of a semiconductor device end product.

9. The method according to claim 1, further comprising:
generating an early warning signal prior to the adjusting step.

10. The method according to claim 1, further comprising:
maintaining the electrical signatures for compensation purposes.

11. The method according to claim 1, further comprising:
controlling shape of distribution of MS modeling parameters.

12. A device comprising:
a simulator for generating a high density model of a semiconductor device during its processing; and
a processor configured to:
collect wafer level data in the form of electrical signatures during processing steps in the production of the semiconductor device;
convert the electrical signatures during each of the processing steps into signal matrix (MS) modeling parameters;
compare the MS modeling parameters to predefined MS modeling parameters; and
adjust at least one processing step based on a result of the comparing step for process control.

13. The device according to claim 12, wherein the processor is configured to collect critical dimension (CD), thickness, resistance (RS), overlay (OVL) and optical critical dimension (OCD) data with metrology systems.

14. The device according to claim 12, wherein the processor is configured to collect the wafer level data with 3^{rd} order modeling or higher.

15. The device according to claim 12, wherein the processor is configured to adjust one or more settings of processing equipment used in the actual production of the semiconductor device.

16. The device according to claim 15, wherein the processor is configured to generate an early warning signal prior to adjusting the one or more settings of processing equipment.

17. The device according to claim 12, wherein the processor is configured to collect wafer level data across the wafer during the processing steps.

18. The device of claim 12, wherein the processor is configured to optimize the wafer level data to improve leakage and performance of a semiconductor device end product.

19. A method comprising:
collecting, by way of a programmed processor, wafer level data in the form of electrical signatures during simulated processing steps in the production of a semiconductor device;
converting the electrical signatures during each of the processing steps into signal matrix (MS) modeling parameters;
comparing the MS modeling parameters to predefined MS modeling parameters;
generating an early warning signal when a defective MS modeling parameter is detected; and
adjusting at least one processing step based on a result of the comparing step for process control.

20. The method according to claim 19, further comprising:
optimizing the wafer level data to improve leakage and performance of the semiconductor device end product.
